(19) United States
(12) Patent Application Publication
(10) Pub. No.: US 2024/0304567 A1
(43) Pub. Date: Sep. 12, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Aya MUTO, Tokyo (JP); Fumihito KAWAHARA, Tokyo (JP)

(73) Assignee: Mitsubishi Electric Corporation, Tokyo (JP)

(21) Appl. No.: 18/538,889

(22) Filed: Dec. 13, 2023

(30) Foreign Application Priority Data
Mar. 9, 2023 (JP) 2023-036137

(51) Int. Cl. H01L 23/00; H01L 21/52; H01L 21/56; H01L 23/053; H01L 23/16; H01L 23/31

(52) U.S. Cl. CPC H01L 23/562; H01L 21/52; H01L 21/56; H01L 23/053; H01L 23/16; H01L 23/3121; H01L 24/48; H01L 24/83; H01L 24/32; H01L 24/73; H01L 2224/32225; H01L 2224/48137; H01L 2224/48225; H01L 2224/73265; H01L 2224/83801

(57) ABSTRACT

A semiconductor device includes a semiconductor element, a case, a beam, and a sealing insulating material. The semiconductor element is mounted on a base plate. The case has a frame shape in plan view. The case is attached to the base plate. The case houses the semiconductor element inside the frame shape. The beam has a flat plate shape. The beam is held by the case. The beam is held over an internal space that is a space inside the frame shape of the case. The sealing insulating material fills the internal space of the case and covers at least a part of the beam. The beam is provided above the semiconductor element and covers the semiconductor element in plan view.

### BACKGROUND OF THE INVENTION

### Field of the Invention

The present disclosure relates to a semiconductor device and a method of manufacturing the semiconductor device.

### Description of the Background Art

In a power semiconductor device, a semiconductor element, such as an insulated gate bipolar transistor (IGBT) or a metal oxide semiconductor field effect transistor (MOSFET), is incorporated. During the operation of the power semiconductor device, the semiconductor element generates heat. Since the linear expansion coefficients of materials constituting the power semiconductor device vary, the semiconductor device is deformed by the heat generation.

A semiconductor module described in Japanese Patent Application Laid-Open No. 2020-107666 has a configuration in which, in order to reduce warpage of the semiconductor module, the linear expansion coefficient of a sealing resin continuously changes from a semiconductor chip toward an upper surface of the sealing resin.

The required value for the maximum operable temperature of the power semiconductor device is rising. Therefore, it is required to further reduce deformation caused by heat generation, such as reducing local deformation around the semiconductor element, as well as controlling deformation of the entire semiconductor device.

### SUMMARY

An object of the present disclosure is to provide a semiconductor device that reduces deformation due to thermal expansion and thermal contraction.

A semiconductor device according to the present disclosure includes a semiconductor element, a case, a beam, and a sealing insulating material. The semiconductor element is mounted on a base plate. The case has a frame shape in plan view. The case is attached to the base plate. The case houses the semiconductor element inside the frame shape. The beam has a flat plate shape. The beam is held by the case. The beam is held over an internal space that is a space inside the frame shape of the case. The sealing insulating material fills the internal space of the case and covers at least a part of the beam. The beam is provided above the semiconductor element and covers the semiconductor element in plan view.

Provided is a semiconductor device that reduces deformation due to thermal expansion and thermal contraction.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment;

FIG. 2 is a cross-sectional view illustrating the configuration of the semiconductor device;

FIG. 3 is a flowchart illustrating a method of manufacturing the semiconductor device according to the first preferred embodiment;

FIG. 4 is a plan view illustrating a configuration of a semiconductor device according to a modification of the first preferred embodiment;

FIG. 5 is a cross-sectional view illustrating the configuration of the semiconductor device;

FIG. 6 is a plan view illustrating a configuration of a semiconductor device according to a second preferred embodiment;

FIG. 7 is a cross-sectional view illustrating the configuration of the semiconductor device;

FIG. 8 is a cross-sectional view illustrating a part of the configuration of the semiconductor device;

FIG. 9 is a plan view illustrating a configuration of a semiconductor device according to a third preferred embodiment;

FIG. 10 is a cross-sectional view illustrating the configuration of the semiconductor device;

FIG. 11 is a cross-sectional view illustrating a part of the configuration of the semiconductor device;

FIG. 12 is a flowchart illustrating a method of manufacturing the semiconductor device according to the third preferred embodiment;

FIG. 13 is a plan view illustrating a configuration of a semiconductor device according to a fourth preferred embodiment;

FIG. 14 is a cross-sectional view illustrating the configuration of the semiconductor device;

FIG. 15 is a plan view illustrating a configuration of a semiconductor device according to a fifth preferred embodiment;

FIG. 16 is a cross-sectional view illustrating the configuration of the semiconductor device;

FIG. 17 is a plan view illustrating a configuration of a semiconductor device according to a modification of the fifth preferred embodiment; and

FIG. 18 is a cross-sectional view illustrating the configuration of the semiconductor device.

### DESCRIPTION OF THE PREFERRED EMBODIMENTS

### First Preferred Embodiment

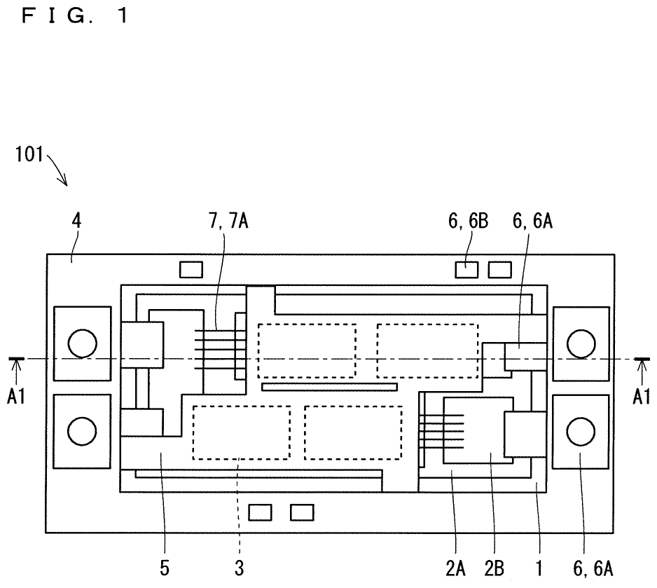

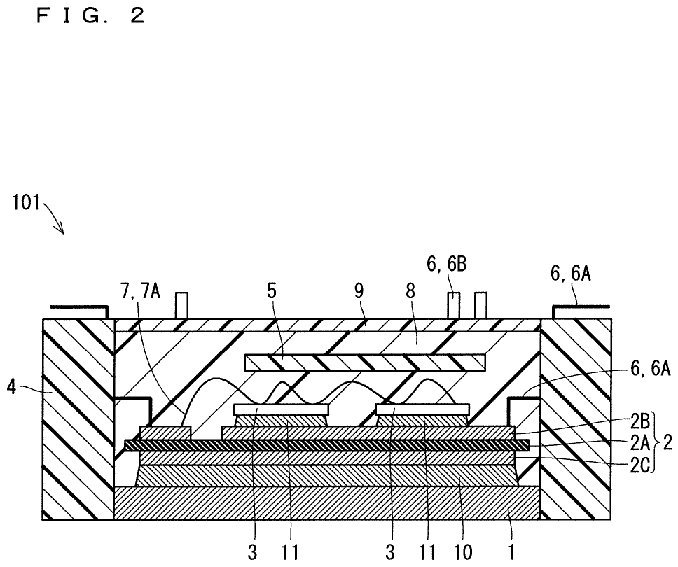

FIG. 1 is a plan view illustrating a configuration of a semiconductor device 101 according to a first preferred embodiment. FIG. 2 is a cross-sectional view illustrating the configuration of the semiconductor device 101. FIG. 2 illustrates a cross section taken along line A1-A1 illustrated in FIG. 1. The semiconductor device 101 includes a base plate 1, an insulating substrate 2, a semiconductor element 3, a case 4, a beam 5, a terminal 6, a wiring 7, a sealing insulating material 8, and a lid 9. In FIG. 1, illustration of the sealing insulating material 8 and the lid 9 is omitted in order to describe the internal configuration of the semiconductor device 101.

The base plate 1 is a plate formed of metal like, for example, copper or aluminum. The base plate 1 has a function of transferring heat generated in an electronic component, such as the semiconductor element 3, to the outside.

The insulating substrate 2 is held by the base plate 1. The insulating substrate 2 includes a substrate body 2A, a front surface pattern 2B, and a back surface pattern 2C. The front surface pattern 2B is provided on the upper surface of the substrate body 2A. The back surface pattern 2C is provided on the lower surface of the substrate body 2A. The substrate body 2A has an insulating property and is formed of, for example, ceramic. The front surface pattern 2B and the back surface pattern 2C are formed of a conductive material such as metal. The back surface pattern 2C is bonded to the base plate 1 via a bonding material 10. The bonding material 10 is, for example, solder, a brazing material, or a sintering material.

The semiconductor element 3 is mounted on the base plate 1 via the insulating substrate 2. In the first preferred embodiment, four semiconductor elements 3 are provided. Each semiconductor element 3 is bonded to the front surface pattern 2B of the insulating substrate 2 via a bonding material 11. The bonding material 11 has conductivity. The bonding material 11 is, for example, solder. When the bonding material 10 is a conductive material, the bonding material 11 may be the same material as the bonding material 10. The semiconductor element 3 according to the first preferred embodiment is a vertical semiconductor element through which a current flows between an upper surface and a lower surface of the semiconductor element 3. The semiconductor element 3 is also referred to as a semiconductor chip. The semiconductor element 3 is formed of, for example, a semiconductor such as Si, or a so-called wide bandgap semiconductor such as SiC, GaN, Ga₂O₃, or diamond. The semiconductor element 3 is a power semiconductor element, a control integrated circuit (IC) for controlling the power semiconductor element, or the like. The semiconductor element 3 includes, for example, an insulated gate bipolar transistor (IGBT), a metal oxide semiconductor field effect transistor (MOSFET), and a Schottky barrier diode. Alternatively, the semiconductor element 3 may include a reverse-conducting IGBT (RC-IGBT) in which an IGBT and a freewheeling diode are formed in one semiconductor substrate.

The case 4 has a frame body having a rectangular shape in plan view. The case 4 houses the insulating substrate 2 and the semiconductor element 3 inside the frame shape. The case 4 is formed of, for example, a resin.

The terminal 6 is a conductor configured to be connectable to an external circuit provided outside the semiconductor device 101. The terminal 6 is, for example, a metal frame in which a flat plate made of metal, such as copper, is processed into a predetermined shape. The terminal 6 in the first preferred embodiment is one component integrated with the case 4. In other words, a part of the terminal 6 is embedded in the case 4 made of resin and fixed. The terminal 6 includes a main terminal 6A and a signal terminal 6B. When the semiconductor element 3 is an IGBT, the main terminal 6A is electrically connected to an emitter or a collector of the IGBT by the wiring 7. The signal terminal 6B is a terminal to be used for controlling or sensing the semiconductor element 3. The main terminal 6A is also referred to as a main electrode, and the signal terminal 6B is also referred to as a signal electrode.

The wiring 7 electrically connects the main terminal 6A and the electrode of the semiconductor element 3. The wiring 7 in the first preferred embodiment includes a plurality of metal wires 7A and the front surface pattern 2B of the insulating substrate 2. The plurality of metal wires 7A connect the main terminals 6A, the front surface patterns 2B, and the semiconductor elements 3. The wiring 7 may include a metal plate instead of the metal wire 7A.

The beam 5 has a flat plate shape. The beam 5 is held by the case 4. In addition, the beam 5 is held over an internal space that is a space inside the frame shape of the case 4. The beam 5 in the first preferred embodiment is one component integrated with the case 4. The beam 5 is formed of the same material as the case 4. The beam 5 and the case 4 are produced by integral molding in a manufacturing process of the semiconductor device 101. For example, the beam 5 and the case 4 are continuously connected without a seam in terms of structure and material.

The beam 5 is formed of an insulating material. The linear expansion coefficient of the beam 5 is smaller than the linear expansion coefficient of the sealing insulating material 8.

Although the beam 5 crosses the internal space that is the space inside the frame shape of the case 4, the beam 5 may not cross as long as it can be held by the case 4. The beam 5 is provided above the semiconductor element 3. The beam 5 covers the semiconductor element 3 in plan view. Although four semiconductor elements 3 are provided in the first preferred embodiment, it is preferable that the beam 5 cover the entire of at least one semiconductor element 3. Here, the beam 5 is disposed so as to cover the entire of the four semiconductor elements 3. In addition, the beam 5 is provided above the wiring 7 passing through a space immediately above the semiconductor element 3. In other words, the beam 5 covers, in plan view, the metal wire 7A passing through the space immediately above the semiconductor element 3.

The beam 5 is provided, in cross-sectional view, between the top of the metal wire 7A and the upper surface of the sealing insulating material 8. The beam 5 is embedded in the inside of the sealing insulating material 8. The beam 5 is provided, for example, at a position within a range from 1.5 mm to 10 mm inclusive from the upper surface of the semiconductor element 3.

The thickness of the beam 5 is, for example, 0.5 mm or more and 8 mm or less. The thickness of the portion, immediately above the semiconductor element 3, of the beam 5 is uniform, but the thickness of the other portion may be non-uniform.

The beam 5 may have any shape as long as the beam 5 is connected to the case 4 and maintains a constant height.

The beam 5 does not cover, in plan view, the entire of the internal space inside the case 4. That is, the internal space includes an opening not covered by the beam 5 in plan view. The opening includes, for example, an inner side surface of the frame body of the case 4 and a cutout portion provided in the beam 5. Alternatively, the opening may be a through hole provided in the beam 5 itself.

The sealing insulating material 8 fills the internal space inside the case 4. The sealing insulating material 8 in the first preferred embodiment covers the entire beam 5, but may cover at least a part of the beam 5. In other words, the whole or at least a part of the beam 5 is embedded in the inside of the sealing insulating material 8. The sealing insulating material 8 seals the surface of the base plate 1, the insulating substrate 2, the semiconductor element 3, the beam 5, a part of the terminal 6, and the metal wire 7A. The sealing insulating material 8 is a resin having curing characteristics. The resin is, for example, a silicone resin or an epoxy resin. The sealing insulating material 8 ensures the withstand voltage of the semiconductor device 101.

The lid 9 is provided above the beam 5. The lid 9 covers the internal space inside the case 4. The lid 9 is attached to, for example, the upper portion of the case 4, and covers the entire of the internal space of the case 4. Note that the lid 9 may not be provided.

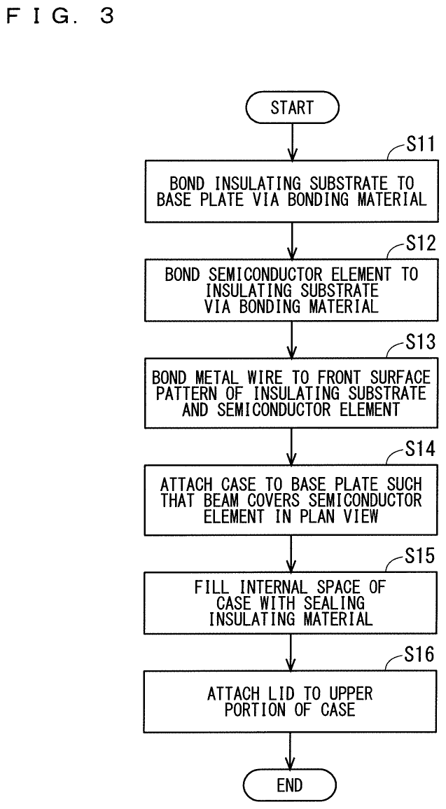

FIG. 3 is a flowchart illustrating a method of manufacturing the semiconductor device 101 according to the first preferred embodiment.

In a step S11, the insulating substrate 2 is bonded to the base plate 1 via the bonding material 10.

In a step S12, the semiconductor element 3 is bonded to the insulating substrate 2 via the bonding material 11. The execution order of the steps S11 and S12 may be reversed or simultaneous. Through the steps S11 and S12, the semiconductor element 3 is mounted on the base plate 1.

In a step S13, the metal wire 7A is bonded to the front surface pattern 2B of the insulating substrate 2 and to the semiconductor element 3. As a result, the front surface pattern 2B of the insulating substrate 2 is electrically connected to the electrode of the semiconductor element 3 via the metal wire 7A.

In a step S14, the case 4 is attached to the base plate 1. At this time, the case 4 is attached to the base plate 1 such that the beam 5 covers the semiconductor element 3 in plan view. The case 4 is fixed to the base plate 1 with, for example, an adhesive or a screw. Through this step S14, the semiconductor element 3 is housed inside the frame shape of the case 4. The case 4 and the beam 5 in the first preferred embodiment are one component manufactured by integral molding. The main terminal 6A is, for example, insert-molded into the case 4. With the case 4 fixed to the base plate 1, the beam 5 is held over the internal space of the case 4 and disposed so as to cover the entire semiconductor element 3 in plan view. In the step S14, the metal wire 7A is bonded to the main terminal 6A and to the front surface pattern 2B of the insulating substrate 2 or the semiconductor element 3. As a result, the main terminal 6A is electrically connected to the front surface pattern 2B or the electrode of the semiconductor element 3 via the metal wire 7A.

In a step S15, a region surrounded by the base plate 1 and the case 4, that is, the internal space of the case 4, is filled with the sealing insulating material 8. After the filling, the sealing insulating material 8 is cured by a curing treatment.

In a step S16, the lid 9 is attached to the upper portion of the case 4 so as to cover the internal space of the case 4.

As described above, the method of manufacturing the semiconductor device 101 includes the steps S11 to S16.

The heat generated in the semiconductor element 3 during the operation of the semiconductor device 101 is dissipated from the back surface of the base plate 1 via the bonding materials 10, 11 and the insulating substrate 2. In addition, the heat generated in the semiconductor element 3 is transferred to an upper portion of the semiconductor device 101 via the metal wire 7A and the sealing insulating material 8. Therefore, a temperature distribution occurs in the semiconductor device 101.

In the semiconductor device 101, the beam 5 is provided so as to cover the upper portion of the semiconductor element 3. The linear expansion coefficient of the beam 5 is smaller than the linear expansion coefficient of the sealing insulating material 8. Therefore, the beam 5 is less likely to be deformed by heat than the sealing insulating material 8. The beam 5 relaxes stress around the semiconductor element 3 due to the heat generation. The beam 5 suppresses deformation of the sealing insulating material 8 immediately above the semiconductor element 3 due to thermal expansion and thermal contraction. The risk of peeling of the sealing insulating material 8 due to thermal expansion and thermal contraction is reduced. Similarly, the beam 5 reduces the risk of peeling and disconnection of the metal wire 7A due to thermal expansion and thermal contraction. As a result, the reliability of the semiconductor device 101 is improved.

To summarize the above, the semiconductor device 101 according to the first preferred embodiment includes the semiconductor element 3, the case 4, the beam 5, and the sealing insulating material 8. The semiconductor element 3 is mounted on the base plate 1. The case 4 has a frame shape in plan view. The case 4 is attached to the base plate 1. The case 4 houses the semiconductor element 3 inside the frame shape. The beam 5 has a flat plate shape. The beam 5 is held by the case 4. The beam 5 is held over an internal space that is a space inside the frame shape of the case 4. The sealing insulating material 8 fills the internal space of the case 4 and covers at least a part of the beam 5. The beam 5 is provided above the semiconductor element 3 and covers the semiconductor element 3 in plan view.

There are various linear expansion coefficients of materials of components constituting the semiconductor device 101. A material having a large linear expansion coefficient is more likely to be deformed by a temperature change, and a material having a small linear expansion coefficient is less likely to be deformed. In the semiconductor device 101, the semiconductor element 3, the wiring 7, and the sealing insulating material 8 have linear expansion coefficients different from each other. However, the linear expansion coefficient of the beam 5 is smaller than the linear expansion coefficient of the sealing insulating material 8, and the beam 5 is less likely to be thermally deformed than the sealing insulating material 8. The beam 5 reinforces rigidity around the semiconductor element 3 that is a heating element. In other words, the beam 5 relaxes stress around the semiconductor element 3 caused by heat generation. According to the semiconductor device 101, deformation around the semiconductor element 3 due to thermal expansion and thermal contraction is reduced.

Even when the required value for the maximum operable temperature of the semiconductor device 101 rises from 150° C. to 200° C., not only deformation of the entire semiconductor device 101 is suppressed, but also local deformation around the semiconductor element 3 is reduced. Since the deformation due to the thermal expansion and thermal contraction is reduced, a decrease in the adhesion of the sealing insulating material 8 and material deterioration are less likely to occur even when the cumulative number of operations of the semiconductor device 101 increases.

Therefore, breakage of the semiconductor device 101 due to peeling of the sealing insulating material 8, disconnection of the wiring 7, or the like is less likely to occur, and the reliability of the semiconductor device 101 is improved.

In the first preferred embodiment, the beam 5 and the case 4 are formed of the same material. Therefore, stress, strain, and warpage around the semiconductor element 3 are controlled by the thickness and the position, in the height direction, of the beam 5.

The beam 5 and the case 4 are one component manufactured by integral molding. The use of such an integrated component improves the assemblability of the semiconductor device 101. The semiconductor device 101 reduces deformation due to thermal expansion and thermal contraction without decreasing the productivity thereof.

The beam 5 does not cover, in plan view, the entire of the internal space inside the case 4. That is, the internal space includes an opening as a region not covered by the beam 5 in plan view. In a state where the case 4 is not covered by the lid 9 in the manufacturing process, the opening forms an open space. Therefore, the opening facilitates filling work of the sealing insulating material 8, and improves the fluidity of the sealing insulating material 8. In addition to that, air bubbles occurring during the filling work are released to the outside from the opening, so that occurrence of a void pool can be avoided. As a result, the insulating property and pressure resistance of the sealing insulating material 8 are improved.

Although the beam 5 illustrated in FIG. 2 is embedded in the inside of the sealing insulating material 8, the sealing insulating material 8 may cover at least a part of the beam 5. In other words, a part of the beam 5 may be embedded in the sealing insulating material 8, and another part of the beam 5 may be exposed from the upper surface of the sealing insulating material 8.

In the manufacturing process, the insulating substrate 2 may be one component integrated with the base plate 1, although not illustrated. When the insulating substrate 2 is integrated with the base plate 1, an insulating layer and the front surface pattern 2B are formed on the base plate 1. In this case, the insulating layer is formed of, for example, a resin.

### Modification of First Preferred Embodiment

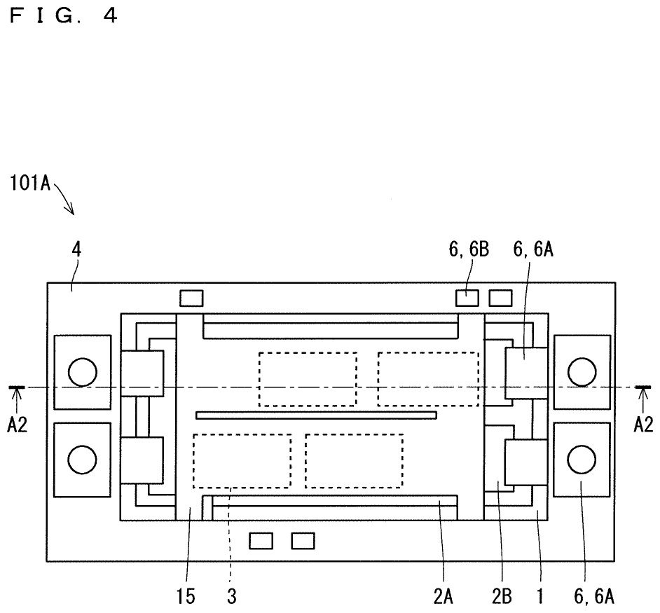

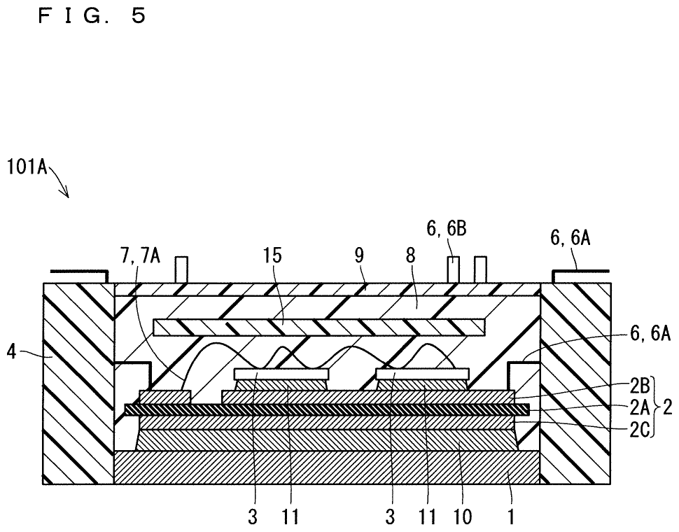

FIG. 4 is a plan view illustrating a configuration of a semiconductor device 101A according to a modification of the first preferred embodiment. FIG. 5 is a cross-sectional view illustrating the configuration of the semiconductor device 101A. FIG. 5 illustrates a cross section taken along line A2-A2 illustrated in FIG. 4. In FIG. 4, illustration of the sealing insulating material 8 and the lid 9 is omitted in order to describe the internal configuration of the semiconductor device 101A.

A beam 15 of the semiconductor device 101A is provided not only immediately above the semiconductor element 3 but also above the plurality of metal wires 7A electrically connected to the main terminal 6A. That is, the beam 15 covers, in plan view, the entire of the semiconductor element 3 and the plurality of metal wires 7A. Note that the lid 9 may not be provided.

According to the semiconductor device 101A as described above, even when the metal wires 7A generate heat equivalently to the semiconductor element 3, deformation due to thermal expansion and thermal contraction accompanying the heat generation is reduced.

### Second Preferred Embodiment

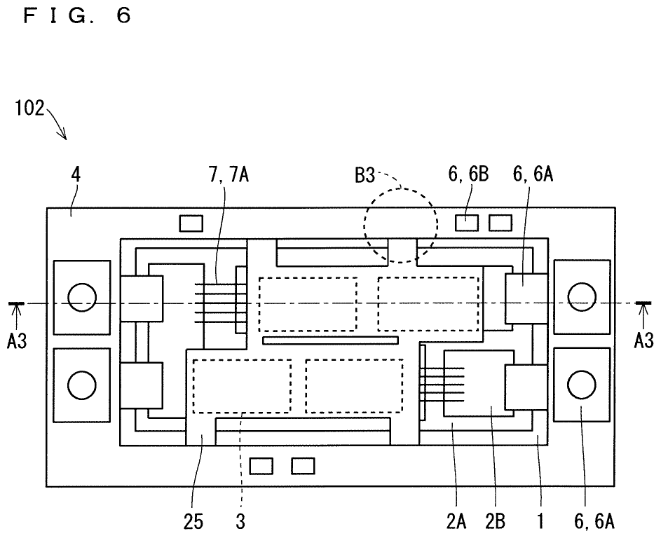

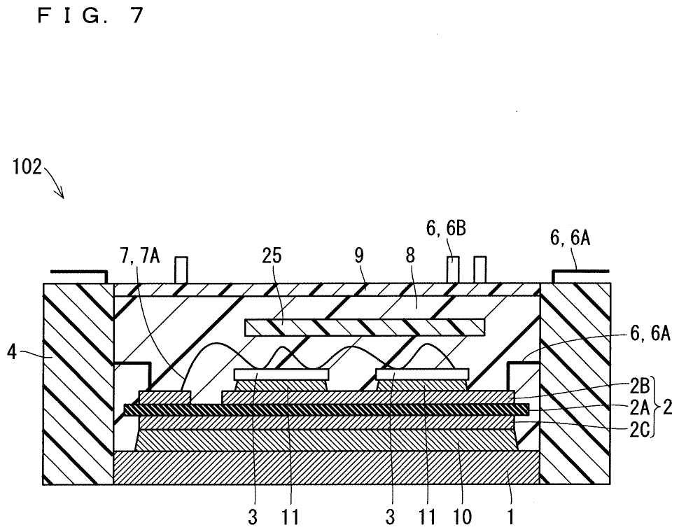

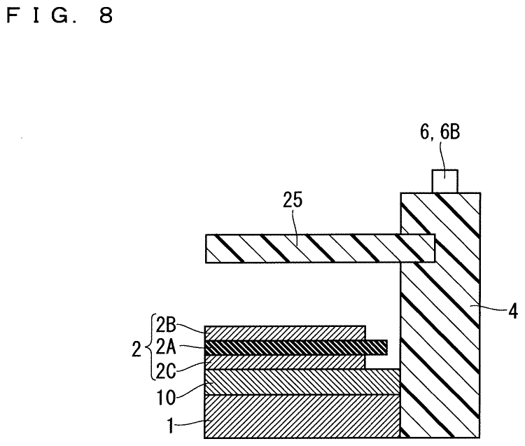

FIG. 6 is a plan view illustrating a configuration of a semiconductor device 102 according to a second preferred embodiment. FIG. 7 is a cross-sectional view illustrating the configuration of the semiconductor device 102. FIG. 7 illustrates a cross section taken along line A3-A3 illustrated in FIG. 6. FIG. 8 is a cross-sectional view illustrating a part of the configuration of the semiconductor device 102. FIG. 8 illustrates a cross section in a region B3 illustrated in FIG. 6. In FIGS. 6 and 8, illustration of the sealing insulating material 8 and the lid 9 is omitted in order to describe the internal configuration of the semiconductor device 102.

The semiconductor device 102 includes the base plate 1, the insulating substrate 2, the semiconductor element 3, the case 4, a beam 25, the terminal 6, the wiring 7, the sealing insulating material 8, and the lid 9. Note that the lid 9 may not be provided.

The beam 25 has a flat plate shape. The beam 25 is held by the case 4. In addition, the beam 25 is held over an internal space that is a space inside the frame shape of the case 4. The beam 25 is formed of a material different from that of the case 4, but is one component integrated with the case 4. The beam 25 and the case 4 can be produced, for example, by integral molding.

The beam 25 includes any one of a resin, glass, a ceramic material, and a metal and clad material covered with an insulator. The beam 25 is any one of a single material plate, a cracked plate, and a composite plate. The cracked plate is a plate partially including a crack, a chip, or the like. The composite plate is formed of, for example, a plurality of glass plates. The linear expansion coefficient of the beam 25 is equivalent to or smaller than the linear expansion coefficient of the sealing insulating material 8.

The beam 25 crosses the internal space that is the space inside the frame shape of the case 4, but may not cross as long as it can be held by the case 4. The beam 25 is provided above the semiconductor element 3. The beam 25 covers the semiconductor element 3 in plan view. The beam 25 in the second preferred embodiment is disposed so as to cover the entire of four semiconductor elements 3. In addition, the beam 25 is provided above the wiring 7 passing through a space immediately above the semiconductor element 3. In other words, the beam 25 covers, in plan view, the metal wire 7A passing through the space immediately above the semiconductor element 3.

The beam 25 is provided, in cross-sectional view, between the top of the metal wire 7A and the upper surface of the sealing insulating material 8. The beam 25 is embedded in the inside of the sealing insulating material 8. The beam 25 is provided, for example, at a position within a range from 1.5 mm to 10 mm inclusive from the upper surface of the semiconductor element 3.

The thickness of the beam 25 is, for example, 0.5 mm or more and 8 mm or less. The thickness of the portion, immediately above the semiconductor element 3, of the beam 25 is uniform, but the thickness of the other portion may be non-uniform.

The beam 25 may have any shape as long as the beam 25 is connected to the case 4 and maintains a constant height.

The beam 25 does not cover, in plan view, the entire of the internal space inside the case 4. That is, the internal space includes an opening not covered by the beam 25 in plan view. The opening includes, for example, an inner side surface of the frame body of the case 4 and a cutout portion provided in the beam 25. Alternatively, the opening may be a through hole provided in the beam 25 itself.

Although the beam 25 illustrated in FIG. 7 is embedded in the inside of the sealing insulating material 8, a part of the beam 25 may be embedded in the sealing insulating material 8, and another part of the beam 25 may be exposed from the upper surface of the sealing insulating material 8.

A method of manufacturing the semiconductor device 102 according to the second preferred embodiment is the same as the manufacturing method according to the first preferred embodiment illustrated in FIG. 3.

A material of the beam 25 is different from a material of the case 4. Therefore, stress, strain, and warpage around the semiconductor element 3 are adjusted not only by the thickness and the position, in the height direction, of the beam 25 but also by a combination of constituent members. The design flexibility in matching linear expansion coefficient is increased as compared with the case where the material of the beam 25 is the same as the material of the case 4. Strain and warpage around the semiconductor element 3 are more finely controlled. Accordingly, the reliability of the semiconductor device 102 is improved.

When the linear expansion coefficient of the beam 25 is equivalent to or smaller than the linear expansion coefficient of the sealing insulating material 8 and close to the linear expansion coefficient of the sealing insulating material 8, the thermal expansion coefficient and the thermal contraction coefficient of the beam 25 are smaller than the thermal expansion coefficient and the thermal contraction coefficient of the sealing insulating material 8. Therefore, the beam 25 plays a role of suppressing expansion and contraction of the sealing insulating material 8. The thickness, the position in the height direction, and the shape of the beam 25 can be freely selected.

When the beam 25 is formed of a material having a linear expansion coefficient smaller than that of the sealing insulating material 8 and close to the semiconductor element 3, peeling at the interface between the sealing insulating material 8 and the beam 25 proceeds earlier than peeling at the interface between the sealing insulating material 8 and the semiconductor element 3. As a result, stress around the semiconductor element 3 is relaxed. Then, the semiconductor element 3 and the sealing insulating material 8 around the wiring 7 are less likely to peel off. The material having a linear expansion coefficient smaller than that of the sealing insulating material 8 and close to the semiconductor element 3 is, for example, glass or ceramic.

When the beam 25 is formed of a metal covered with an insulator, the heat dissipation of the beam 25 is better than the heat dissipation of the sealing insulating material 8. Therefore, heat dissipation, to an upper part, of the semiconductor device 102 is improved. The metal covered with an insulator is, for example, copper or aluminum.

The beam 25 in the semiconductor device 102 may be provided not only immediately above the semiconductor element 3 but also above the plurality of metal wires 7A electrically connected to the main terminal 6A. That is, the beam 25 may cover, in plan view, the entire of the semiconductor element 3 and the plurality of metal wires 7A, as in the modification of the first preferred embodiment. Such a configuration is effective when the metal wire 7A generates heat equivalently to the semiconductor element 3.

### Third Preferred Embodiment

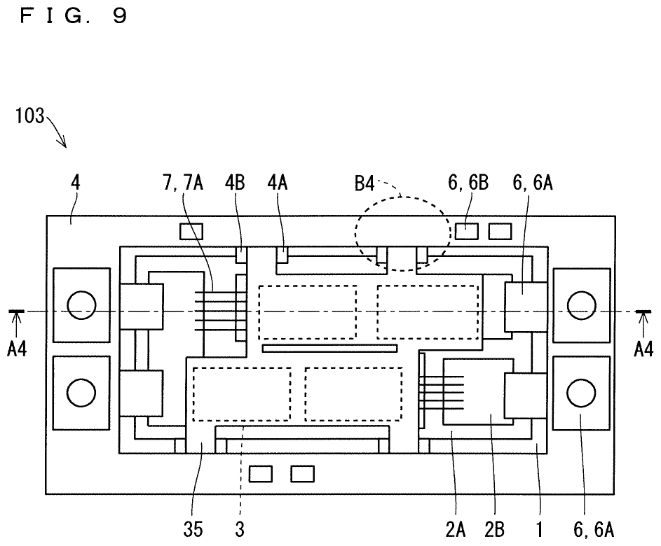

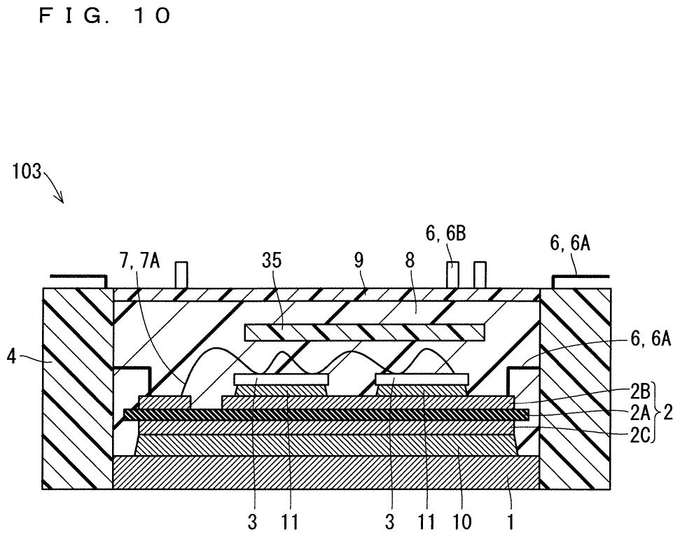

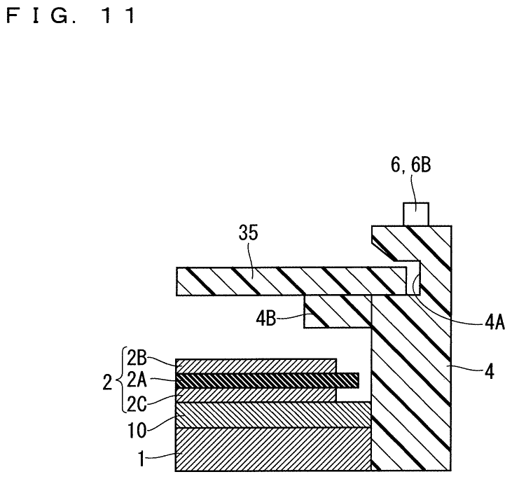

FIG. 9 is a plan view illustrating a configuration of a semiconductor device 103 according to a third preferred embodiment. FIG. 10 is a cross-sectional view illustrating the configuration of the semiconductor device 103. FIG. 10 illustrates a cross section taken along line A4-A4 illustrated in FIG. 9. FIG. 11 is a cross-sectional view illustrating a part of the configuration of the semiconductor device 103. FIG. 11 illustrates a cross section in a region B4 illustrated in FIG. 9. In FIGS. 9 and 11, illustration of the sealing insulating material 8 and the lid 9 is omitted in order to describe the internal configuration of the semiconductor device 103.

The semiconductor device 103 includes the base plate 1, the insulating substrate 2, the semiconductor element 3, the case 4, a beam 35, the terminal 6, the wiring 7, the sealing insulating material 8, and the lid 9. Note that the lid 9 may not be provided.

The beam 35 has a flat plate shape. The beam 35 is held by the case 4. In addition, the beam 35 is held over an internal space that is a space inside the frame shape of the case 4. The beam 35 in the third preferred embodiment is a component different from the case 4.

The beam 35 includes a fitting portion to fit into a recess portion 4A of the case 4 to be described later. In other words, the beam 35 is held by the case 4 by fitting into the recess portion 4A of the case 4. The fitting portion is provided in a peripheral edge portion of the beam 35.

The beam 35 may be formed of the same material as the case 4, or may be formed of a different material. The beam 35 includes any one of a resin, glass, a ceramic material, and a metal and clad material covered with an insulator. Furthermore, the beam 35 is any one of a single material plate, a cracked plate, and a composite plate. The cracked plate is a plate partially including a crack, a chip, or the like. The composite plate is formed of, for example, a plurality of glass plates. The linear expansion coefficient of the beam 35 is equivalent to or smaller than the linear expansion coefficient of the sealing insulating material 8.

The beam 35 crosses the internal space that is the space inside the frame shape of the case 4, but may not cross as long as it can be held by the case 4. The beam 35 is provided above the semiconductor element 3. The beam 35 covers the semiconductor element 3 in plan view. The beam 35 in the third preferred embodiment is disposed so as to cover the entire of four semiconductor elements 3. In addition, the beam 35 is provided above the wiring 7 passing through a space immediately above the semiconductor element 3. In other words, the beam 35 covers, in plan view, the metal wire 7A passing through the space immediately above the semiconductor element 3.

The beam 35 is provided, in cross-sectional view, between the top of the metal wire 7A and the upper surface of the sealing insulating material 8. The beam 35 is embedded in the inside of the sealing insulating material 8. The beam 35 is provided, for example, at a position within a range from 1.5 mm to 10 mm inclusive from the upper surface of the semiconductor element 3.

The thickness of the beam 35 is, for example, 0.5 mm or more and 8 mm or less. The thickness of the portion, immediately above the semiconductor element 3, of the beam 35 is uniform, but the thickness of the other portion may be non-uniform.

The beam 35 may have any shape as long as the beam 35 is connected to the case 4 and maintains a constant height.

The beam 35 does not cover, in plan view, the entire of the internal space inside the case 4. That is, the internal space includes an opening not covered by the beam 35 in plan view. The opening includes, for example, an inner side surface of the frame body of the case 4 and a cutout portion provided in the beam 35. Alternatively, the opening may be a through hole provided in the beam 35 itself.

Although the beam 35 illustrated in FIG. 10 is embedded in the inside of the sealing insulating material 8, a part of the beam 35 may be embedded in the sealing insulating material 8, and another part of the beam 35 may be exposed from the upper surface of the sealing insulating material 8.

As illustrated in FIG. 11, the case 4 includes the recess portion 4A and a protrusion portion 4B on an inner side surface of the frame body constituting the frame shape. The recess portion 4A and the protrusion portion 4B are structures for holding the beam 35. The fitting portion of the beam 35 fits into the recess portion 4A. The protrusion portion 4B supports the fitting portion of the beam 35.

The depth of the recess portion 4A is shorter than the width of the case 4. The width and thickness of the recess portion 4A are larger than the width and thickness of the fitting portion of the beam 35 by 0.01 mm or more and 2 mm or less. With such a structure, the beam 35 is less likely to come off from the recess portion 4A. A cutout portion shallower than the depth of the recess portion 4A is provided in an upper portion of the inlet of the recess portion 4A. The cross-sectional area of the inlet of the recess portion 4A is larger than the cross-sectional area of the deep portion of the recess portion 4A. The recess portion 4A may be a groove.

The protrusion portion 4B may be formed so as to go around the inner periphery of the frame body of the case 4 in addition to the position corresponding to the fitting portion of the beam 35. The protrusion portion 4B may have a groove or the like for positioning the beam 35. The protrusion portion 4B may be a rib.

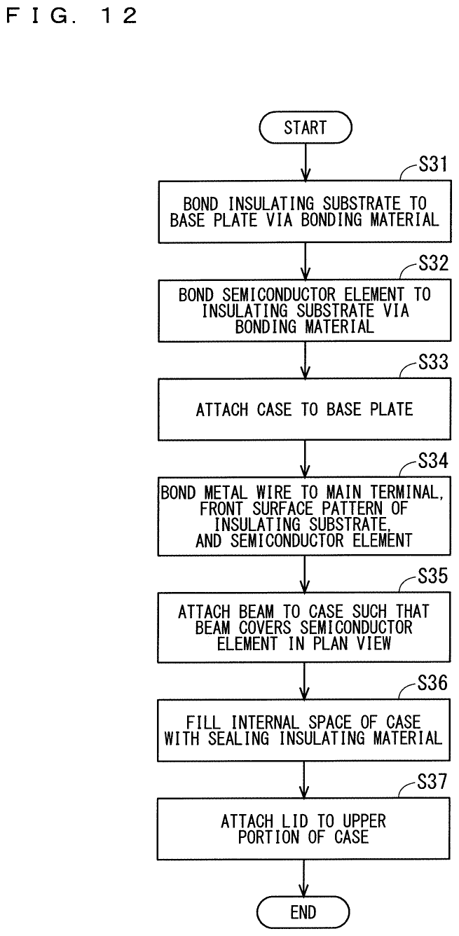

FIG. 12 is a flowchart illustrating a method of manufacturing the semiconductor device 103 according to the third preferred embodiment.

In a step S31, the insulating substrate 2 is bonded to the base plate 1 via the bonding material 10.

In a step S32, the semiconductor element 3 is bonded to the insulating substrate 2 via the bonding material 11. The execution order of the steps S31 and S32 may be reversed or simultaneous. Through the steps S31 and S32, the semiconductor element 3 is mounted on the base plate 1.

In a step S33, the case 4 is attached to the base plate 1. The case 4 is fixed to the base plate 1 with, for example, an adhesive or a screw. Through this step S33, the semiconductor element 3 is housed inside the frame shape of the case 4. The case 4 and the main terminal 6A are one component manufactured by integral molding and insert molding. With the case 4 fixed to the base plate 1, the terminal 6 is disposed at a predetermined position.

In a step S34, the metal wire 7A is bonded to the main terminal 6A, the front surface pattern 2B of the insulating substrate 2, and the semiconductor element 3. As a result, the front surface pattern 2B of the insulating substrate 2 is electrically connected to the electrode of the semiconductor element 3 via the metal wire 7A. Similarly, the main terminal 6A is electrically connected to the front surface pattern 2B or the electrode of the semiconductor element 3 via the metal wire 7A.

In a step S35, the beam 35 is attached to the case 4 so as to cover the semiconductor element 3 in plan view. Here, the beam 35 is disposed, as an example, to be held over the internal space of the case 4 and so as to cover the entire of the semiconductor element 3 in plan view. In this step S35, the fitting portion of the beam 35 fits into the recess portion 4A of the case 4. The beam 35 is held by the recess portion 4A of the case 4 and the protrusion portion 4B.

In a step S36, a region surrounded by the base plate 1 and the case 4, that is, the internal space of the case 4, is filled with the sealing insulating material 8. After the filling, the sealing insulating material 8 is cured by a curing treatment.

In a step S37, the lid 9 is attached to the upper portion of the case 4 so as to cover the internal space of the case 4.

As described above, the method of manufacturing the semiconductor device 103 includes the steps S31 to S37.

Also, in such a semiconductor device 103, effects similar to those of the first and second preferred embodiments can be obtained. The beam 35 in the third preferred embodiment is a component prepared separately from the case 4. In the manufacturing process of the semiconductor device 103, the beam 35 is fitted into the recess portion 4A of the case 4, whereby the beam 35 is held by the case 4. After the case 4 is mounted on the base plate 1, a bonding process of the wiring 7 can be performed.

When the beam 35 is a component integrally molded with the case 4, peeling or separation may occur in the molding process depending on the material constituting the component. The beam 35 and the case 4 in the third preferred embodiment are prepared as components different from each other. Regardless of compatibility in the integral molding process, the materials of the beam 35 and the case 4 can be arbitrarily selected.

The beam 35 fits into the recess portion 4A of the case 4 and is supported by the protrusion portion 4B. Therefore, the rigidity of the beam 35 is improved. In addition to that, upper, lower, left, and right portions of the beam 35 are fixed by the recess portion 4A of the case 4 and the protrusion portion 4B. Therefore, at the time of filling with the sealing insulating material 8, the beam 35 is prevented from rising, and further, the position of the beam 35 is prevented from being shifted. In addition, the cutout is provided at the inlet of the recess portion 4A, and thus the beam 35 can be easily inserted into the recess portion 4A.

### Fourth Preferred Embodiment

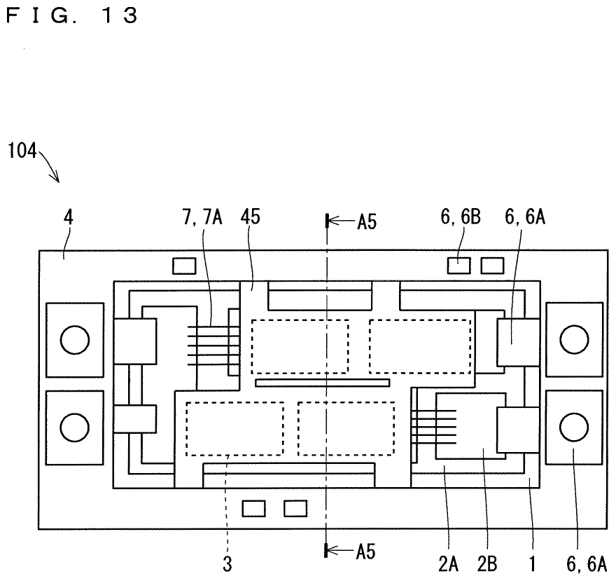

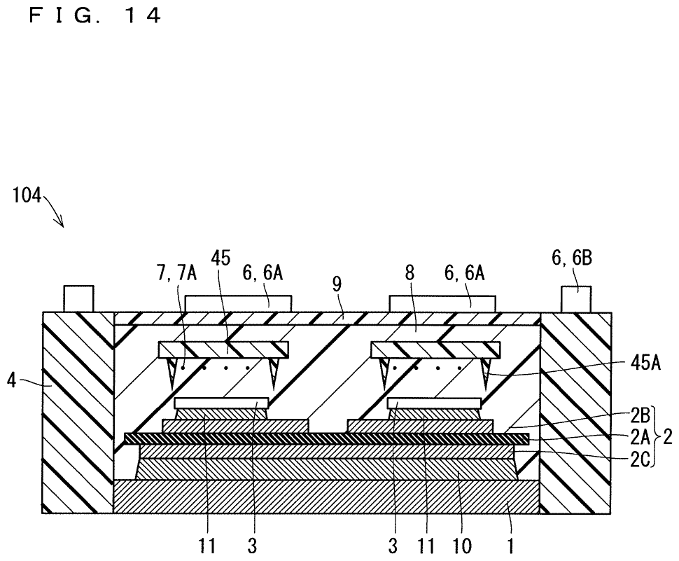

FIG. 13 is a plan view illustrating a configuration of a semiconductor device 104 according to a fourth preferred embodiment. FIG. 14 is a cross-sectional view illustrating the configuration of the semiconductor device 104. FIG. 14 illustrates a cross section taken along line A5-A5 illustrated in FIG. 13. In FIG. 13, illustration of the sealing insulating material 8 and the lid 9 is omitted in order to describe the internal configuration of the semiconductor device 104.

The semiconductor device 104 includes the base plate 1, the insulating substrate 2, the semiconductor element 3, the case 4, a beam 45, the terminal 6, the wiring 7, the sealing insulating material 8, and the lid 9. Note that the lid 9 may not be provided.

The beam 45 has a flat plate shape. The beam 45 is held by the case 4. In addition, the beam 45 is held over an internal space that is a space inside the frame shape of the case 4. As in the third preferred embodiment, the beam 45 may be formed of the same material as the case 4, or may be formed of a different material. The beam 45 includes any one of a resin, glass, a ceramic material, and a metal and clad material covered with an insulator. Furthermore, the beam 45 may be any one of a single material plate, a cracked plate, and a composite plate. The cracked plate is a plate partially including a crack, a chip, or the like. The composite plate is formed of, for example, a plurality of glass plates. The linear expansion coefficient of the beam 45 is equivalent to or smaller than the linear expansion coefficient of the sealing insulating material 8.

The beam 45 crosses the internal space that is the space inside the frame shape of the case 4, but may not cross as long as it can be held by the case 4. The beam 45 is provided above the semiconductor element 3. The beam 45 covers the semiconductor element 3 in plan view. The beam 45 in the fourth preferred embodiment is disposed so as to cover the entire of four semiconductor elements 3. In addition, the beam 45 is provided above the wiring 7 passing through a space immediately above the semiconductor element 3. In other words, the beam 45 covers, in plan view, the metal wire 7A passing through the space immediately above the semiconductor element 3.

The beam 45 has a protrusion 45A on the lower surface of the flat plate shape. The protrusion 45A is located immediately above the peripheral edge portion of the semiconductor element 3 in plan view. The protrusion 45A is not in contact with the semiconductor element 3 and the wiring 7. The protrusion 45A is formed by etching, molding, adhesion, or the like.

The main body of the beam 45 is provided, in cross-sectional view, between the top of the metal wire 7A and the upper surface of the sealing insulating material 8. The protrusion 45A may be located below the top of the metal wire 7A. The beam 45 is embedded in the inside of the sealing insulating material 8. The beam 45 is provided, for example, at a position within a range from 1.5 mm to 10 mm inclusive from the upper surface of the semiconductor element 3.

The thickness of the beam 45 is, for example, 0.5 mm or more and 8 mm or less. The thickness of the portion, immediately above the semiconductor element 3, of the beam 45 is uniform, but the thickness of the other portion may be non-uniform.

The beam 45 may have any shape as long as the beam 45 is connected to the case 4 and maintains a constant height.

The beam 45 does not cover, in plan view, the entire of the internal space inside the case 4. That is, the internal space includes an opening not covered by the beam 45 in plan view. The opening includes, for example, an inner side surface of the frame body of the case 4 and a cutout portion provided in the beam 45. Alternatively, the opening may be a through hole provided in the beam 45 itself.

Although the beam 45 illustrated in FIG. 14 is embedded in the inside of the sealing insulating material 8, a part of the beam 45 may be embedded in the sealing insulating material 8, and another part of the beam 45 may be exposed from the upper surface of the sealing insulating material 8.

According to such a semiconductor device 104, when a crack occurs in the sealing insulating material 8 from the peripheral edge portion of the semiconductor element 3, the direction of development of the crack is guided toward the protrusion 45A. As a result, a short circuit between the semiconductor element 3 and a different potential part is prevented.

The protrusion 45A of the beam 45 may be applied to the semiconductor device according to any one of the first to third preferred embodiments. Even in this case, the same effects as those of the fourth preferred embodiment can be obtained.

### Fifth Preferred Embodiment

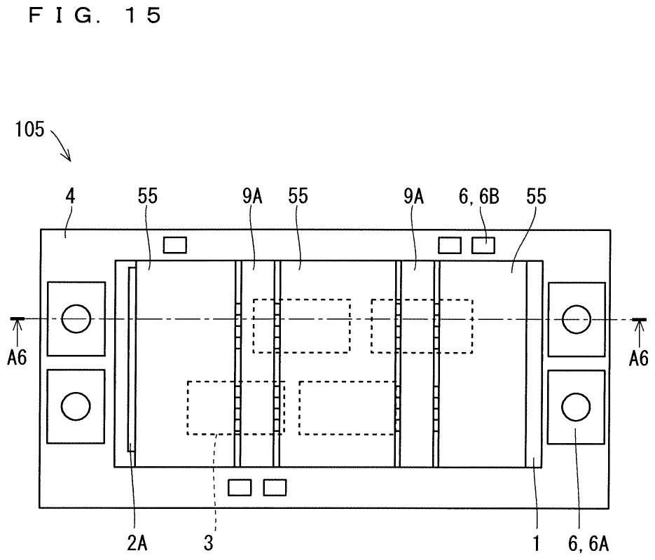

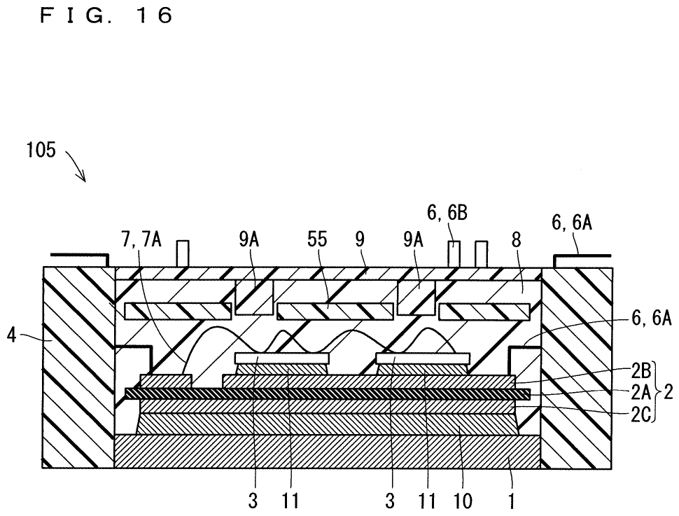

FIG. 15 is a plan view illustrating a configuration of a semiconductor device 105 according to a fifth preferred embodiment. FIG. 16 is a cross-sectional view illustrating the configuration of the semiconductor device 105. FIG. 16 illustrates a cross section taken along line A6-A6 illustrated in FIG. 15. In FIG. 15, illustration of the sealing insulating material 8 and the lid 9 is omitted in order to describe the internal configuration of the semiconductor device 105.

The semiconductor device 105 includes the base plate 1, the insulating substrate 2, the semiconductor element 3, the case 4, a beam 55, the terminal 6, the wiring 7, the sealing insulating material 8, and the lid 9.

The lid 9 includes a plurality of case beam portions 9A provided on the lower surface of the lid 9. In the fifth preferred embodiment, two case beam portions 9A are provided. Each case beam portion 9A does not cover the entire of the semiconductor element 3 in plan view. A part of each case beam portion 9A is located immediately above a part of the semiconductor element 3. The case beam portion 9A is integrated with the lid 9. The case beam portion 9A is produced by integral molding with the lid 9. The lid 9 is fixed to the case 4 so as to close the internal space of the case 4. The case beam portion 9A reduces warpage of or reinforces the rigidity of the entire of the semiconductor device 105.

The beam 55 has a flat plate shape. The beam 55 is held by the case 4. In addition, the beam 55 is held over an internal space that is a space inside the frame shape of the case 4. The beam 55 crosses the internal space that is the space inside the frame shape of the case 4, but may not cross as long as it can be held by the case 4.

The beam 55 is provided so as not to overlap the plurality of case beam portions 9A in plan view. In the fifth preferred embodiment, three beams 55 are provided. Among the three beams 55, the central beam 55 is disposed between the two case beam portions 9A. Each of the two outer beams 55 is disposed between the case beam portion 9A and the frame body of the case 4. The beam 55 is provided above the semiconductor element 3. The central beam 55 is disposed so as to cover the entire of one of the four semiconductor elements 3. In addition, the beam 55 is provided above the wiring 7 passing through a space immediately above the semiconductor element 3. In other words, the beam 55 covers, in plan view, the metal wire 7A passing through the space immediately above the semiconductor element 3.

As in the third preferred embodiment, the beam 55 may be formed of the same material as the case 4, or may be formed of a different material. The beam 55 includes any one of a resin, glass, a ceramic material, and a metal and clad material covered with an insulator. The beam 55 may be any one of a single material plate, a cracked plate, and a composite plate. The cracked plate is a plate partially including a crack, a chip, or the like. The composite plate is formed of, for example, a plurality of glass plates.

The central beam 55 and the outer beams 55 may be formed of the same material as each other, or may be formed of different materials. The central beam 55 and the outer beams 55 may have the same structure as each other, or may have different structures. The beam 55 may have, for example, a structure in which a plurality of materials are combined.

The thickness of the beam 55 is, for example, 0.5 mm or more and 8 mm or less. The thickness of the portion, immediately above the semiconductor element 3, of the beam 55 is uniform, but the thickness of the other portion may be non-uniform.

Although the beam 55 illustrated in FIG. 16 is embedded in the inside of the sealing insulating material 8, a part of the beam 55 may be embedded in the sealing insulating material 8, and another part of the beam 55 may be exposed from the upper surface of the sealing insulating material 8.

Since such a semiconductor device 105 has a structure in which the beams 55 and the case beam portions 9A are combined with each other, deformation and stress around the semiconductor element 3 are relaxed. Even in a case where the base plate 1 may be deformed so as to be rapidly warped, the semiconductor device 105 suppresses such deformation. Then, the semiconductor device 105 prevents a crack from occurring in a structure inside the semiconductor device 105. For example, when the sealing insulating material 8 is made of a material that requires high-temperature heating, the sealing insulating material 8 contracts during the curing treatment of the sealing insulating material 8, and stress that causes warpage is remarkably applied to the base plate 1. Even in such a case, the semiconductor device 105 relaxes the stress.

In addition, the configuration, in which the plurality of case beam portions 9A and the plurality of beams 55 are combined, enables fine control of warpage. In addition, the heat dissipation of the upper portion of the semiconductor device 105 can be improved.

In FIG. 15, a part of the case beam portion 9A is located immediately above the semiconductor element 3, but the case beam portion 9A may not be located immediately above the semiconductor element 3 at all.

Although it has been described above that the case beam portion 9A is integrated with the lid 9, the case beam portion 9A may be integrated with the case 4 alone, and in this case, the lid 9 may not be provided. This also applies to a modification of the fifth preferred embodiment to be described below.

### Modification of Fifth Preferred Embodiment

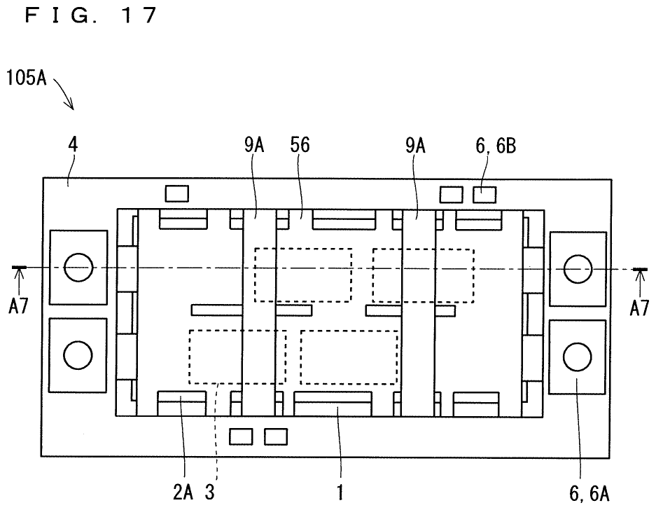

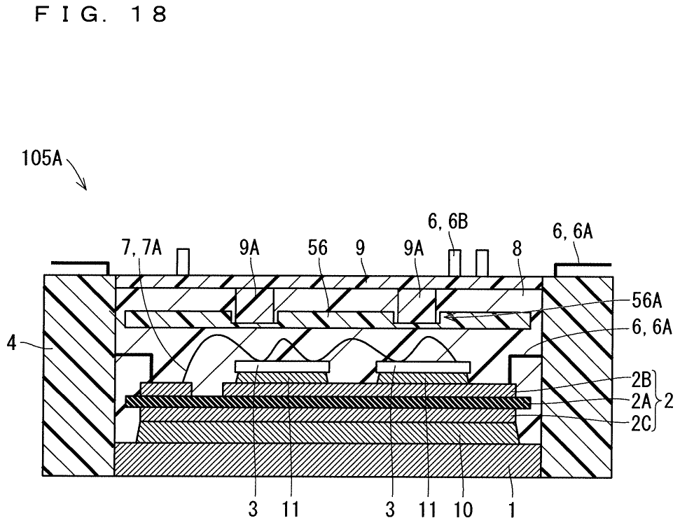

FIG. 17 is a plan view illustrating a configuration of a semiconductor device 105A according to a modification of the fifth preferred embodiment. FIG. 18 is a cross-sectional view illustrating the configuration of the semiconductor device 105A. FIG. 18 illustrates a cross section taken along line A7-A7 illustrated in FIG. 17. In FIG. 17, illustration of the sealing insulating material 8 and the lid 9 is omitted in order to describe the internal configuration of the semiconductor device 105A.

A beam 56 of the semiconductor device 105A includes a plurality of stepped portions 56A. In the modification of the fifth preferred embodiment, two stepped portions 56A are provided. The thickness of each of the plurality of stepped portions 56A is thinner than the thicknesses of the beam 56 other than the stepped portion 56A.

The stepped portion 56A is located immediately below the case beam portion 9A. That is, the beam 56 is provided such that the plurality of stepped portions 56A overlap the plurality of case beam portions 9A in plan view.

Unlike in the fifth preferred embodiment, the beam 56 is a single plate and is continuous. In the left-right direction of FIG. 17, there is no gap between the beam 56 and the case beam portion 9A. When stress is applied to the semiconductor device 105A, such a configuration prevents the stress from concentrating on the semiconductor element 3 located immediately below the gap.

In addition, the beam 56 has a central portion located between the two case beam portions 9A and two outer portions each located between the case beam portion 9A and the frame body of the case 4. The rigidity of the outer portion may be lower than the rigidity of the central portion. Accordingly, a warping shape of the base plate 1 is controlled. The rigidity of the beam 56 is adjusted by the thickness and elastic modulus of the beam 56.

In the present disclosure, each preferred embodiment can be freely combined or appropriately modified or omitted.

Hereinafter, various aspects of the present disclosure will be collectively described as Appendices.

### (Appendix 1)

A semiconductor device comprising:
a semiconductor element mounted on a base plate;
a case that has a frame shape in plan view, is attached to the base plate, and houses the semiconductor element inside the frame shape;
a beam that has a flat plate shape, is held by the case, and is held over an internal space that is a space inside the frame shape of the case; and
a sealing insulating material that fills the internal space of the case and covers at least a part of the beam, wherein
the beam is provided above the semiconductor element and covers the semiconductor element in plan view.

### (Appendix 2)

The semiconductor device according to Appendix 1, wherein the beam is provided above a wiring passing through a space immediately above the semiconductor element, and covers the wiring in plan view.

### (Appendix 3)

The semiconductor device according to Appendix 1 or 2, wherein the internal space includes an opening not covered by the beam in plan view.

### (Appendix 4)

The semiconductor device according to any one of Appendices 1 to 3, wherein
the beam includes any one of a resin, glass, a ceramic material, and a metal and clad material covered with an insulator, and the beam is formed of any one of a single material plate, a cracked plate, and a composite plate, and
a linear expansion coefficient of the beam is smaller than a linear expansion coefficient of the sealing insulating material.

### (Appendix 5)

The semiconductor device according to any one of Appendices 1 to 4, wherein the beam is a component integrated with the case.

### (Appendix 6)

The semiconductor device according to any one of Appendices 1 to 5, wherein
the case includes a recess portion on an inner side surface of a frame body constituting the frame shape, and
the beam fits into the recess portion of the case.

### (Appendix 7)

The semiconductor device according to any one of Appendices 1 to 6, wherein the beam has a protrusion on a lower surface of the flat plate shape.

### (Appendix 8)

The semiconductor device according to any one of Appendices 1 to 7, comprising a plurality of case beam portions provided on an upper side of the beam, wherein
the beam is provided between the plurality of case beam portions in plan view.

### (Appendix 9)

The semiconductor device according to Appendix 8, further comprising a lid that covers the internal space, wherein
the plurality of case beam portions are provided on a lower surface of the lid.

### (Appendix 10)

The semiconductor device according to Appendix 8, wherein the plurality of case beam portions are components integrated with the case.

### (Appendix 11)

The semiconductor device according to any one of Appendices 8 to 10, wherein
the beam includes a plurality of stepped portions,
a thickness of each of the plurality of stepped portions is smaller than a thickness of the beam other than the plurality of stepped portions, and
the beam is provided such that the plurality of stepped portions overlap the plurality of case beam portions in plan view.

### (Appendix 12)

A method of manufacturing a semiconductor device, the method comprising the steps of:
mounting a semiconductor element on a base plate;
attaching, to the base plate, a case that has a frame shape in plan view and is integrated with a beam that has a flat plate shape and is held over an internal space that is a space inside the frame shape of the case; and
filling the internal space with a sealing insulating material, wherein
in the step of attaching the case to the base plate, the case is attached to the base plate such that the semiconductor element is housed inside the frame shape and the beam is provided above the semiconductor element to cover the semiconductor element in plan view, and
in the step of filling with the sealing insulating material, the filling is performed such that the sealing insulating material covers at least a part of the beam.

### (Appendix 13)

A method of manufacturing a semiconductor device, the method comprising the steps of:
mounting a semiconductor element on a base plate;
attaching, to the base plate, a case that has a frame shape in plan view and includes a recess portion on an inner side surface of a frame body constituting the frame shape such that the semiconductor element is housed inside the frame shape;
attaching, to the case, a beam that has a flat plate shape and is held over an internal space that is a space inside the frame shape of the case; and
filling the internal space with a sealing insulating material, wherein
in the step of attaching the beam to the case, the beam is attached to the case such that the beam fits into the recess portion of the case and is provided above the semiconductor element to cover the semiconductor element in plan view, and
in the step of filling with the sealing insulating material, the filling is performed such that the sealing insulating material covers at least a part of the beam.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor element mounted on a base plate;
a case that has a frame shape in plan view, is attached to the base plate, and houses the semiconductor element inside the frame shape;
a beam that has a flat plate shape, is held by the case, and is held over an internal space that is a space inside the frame shape of the case; and
a sealing insulating material that fills the internal space of the case and covers at least a part of the beam, wherein
the beam is provided above the semiconductor element and covers the semiconductor element in plan view.

2. The semiconductor device according to claim 1, wherein the beam is provided above a wiring passing through a space immediately above the semiconductor element, and covers the wiring in plan view.

3. The semiconductor device according to claim 1, wherein the internal space includes an opening not covered by the beam in plan view.

4. The semiconductor device according to claim 1, wherein
the beam includes any one of a resin, glass, a ceramic material, and a metal and clad material covered with an insulator, and the beam is formed of any one of a single material plate, a cracked plate, and a composite plate, and
a linear expansion coefficient of the beam is smaller than a linear expansion coefficient of the sealing insulating material.

5. The semiconductor device according to claim 1, wherein the beam is a component integrated with the case.

6. The semiconductor device according to claim 1, wherein
the case includes a recess portion on an inner side surface of a frame body constituting the frame shape, and
the beam fits into the recess portion of the case.

7. The semiconductor device according to claim 1, wherein the beam has a protrusion on a lower surface of the flat plate shape.

8. The semiconductor device according to claim 1, comprising a plurality of case beam portions provided on an upper side of the beam, wherein
the beam is provided between the plurality of case beam portions in plan view.

9. The semiconductor device according to claim 8, further comprising a lid that covers the internal space, wherein
the plurality of case beam portions are provided on a lower surface of the lid.

10. The semiconductor device according to claim 8, wherein the plurality of case beam portions are components integrated with the case.

11. The semiconductor device according to claim 8, wherein
the beam includes a plurality of stepped portions,
a thickness of each of the plurality of stepped portions is smaller than a thickness of the beam other than the plurality of stepped portions, and
the beam is provided such that the plurality of stepped portions overlap the plurality of case beam portions in plan view.

12. A method of manufacturing a semiconductor device, the method comprising the steps of:
mounting a semiconductor element on a base plate;
attaching, to the base plate, a case that has a frame shape in plan view and is integrated with a beam that has a flat plate shape and is held over an internal space that is a space inside the frame shape of the case; and
filling the internal space with a sealing insulating material, wherein
in the step of attaching the case to the base plate, the case is attached to the base plate such that the semiconductor element is housed inside the frame shape and the beam is provided above the semiconductor element to cover the semiconductor element in plan view, and
in the step of filling with the sealing insulating material, the filling is performed such that the sealing insulating material covers at least a part of the beam.

13. A method of manufacturing a semiconductor device, the method comprising the steps of:
mounting a semiconductor element on a base plate;
attaching, to the base plate, a case that has a frame shape in plan view and includes a recess portion on an inner side surface of a frame body constituting the frame shape such that the semiconductor element is housed inside the frame shape;
attaching, to the case, a beam that has a flat plate shape and is held over an internal space that is a space inside the frame shape of the case; and
filling the internal space with a sealing insulating material, wherein
in the step of attaching the beam to the case, the beam is attached to the case such that the beam fits into the recess portion of the case and is provided above the semiconductor element to cover the semiconductor element in plan view, and
in the step of filling with the sealing insulating material, the filling is performed such that the sealing insulating material covers at least a part of the beam.
